(19) United States
(12) Patent Application Publication
(10) Pub. No.: US 2024/0113263 A1
(43) Pub. Date: Apr. 4, 2024

(54) LIGHT-EMITTING DEVICE

(71) Applicant: NICHIA CORPORATION, Anan-shi (JP)

(72) Inventor: Yoshiyuki AIHARA, Tokushima-shi (JP)

(73) Assignee: NICHIA CORPORATION, Anan-shi (JP)

(21) Appl. No.: 18/466,070

(22) Filed: Sep. 13, 2023

(30) Foreign Application Priority Data
Sep. 29, 2022 (JP) 2022-155817

(51) Int. Cl. H01L 33/40; H01L 33/44

(52) U.S. Cl. CPC H01L 33/405; H01L 33/44

(57) ABSTRACT

A light-emitting device includes a light-emitting element a semiconductor structure body including an n-side layer, a p-side layer, and an active layer, the n-side layer including an n-side exposed surface exposed from the active layer and the p-side layer in a plan view. The semiconductor structure body includes a side surface connecting the n-side exposed surface and an upper surface of the p-side layer. An insulating film includes a first opening exposing the n-side exposed surface, and a second opening positioned above the upper surface of the p-side layer. An n-side electrode includes a first part positioned above the upper surface of the p-side layer with the insulating film interposed, a second part electrically connected with the n-side exposed surface in the first opening and electrically connected with the first part located at the insulating film covering the side surface, and a third opening that exposes the insulating film covering the side surface of the semiconductor structure body. A light-reflective member contacts the insulating film in the third opening.

### CROSS-REFERENCE TO RELATED APPLICATION

This application claims priority to Japanese Patent Application No. 2022-155817, filed on Sep. 29, 2022, the disclosure of which is hereby incorporated by reference in its entirety.

### BACKGROUND

The disclosure relates to a light-emitting device.

There is known a light-emitting device having a structure in which an n-side electrode is connected to an n-side exposed surface of an n-side layer exposed from under an active layer and a p-side layer, and in which light is extracted from the side of the light-emitting device at the side of the n-side layer opposite to the n-side exposed surface.

### SUMMARY

An object of certain embodiments of the disclosure is to provide a light-emitting device in which the light extraction efficiency can be increased.

In an embodiment of the disclosure, a light-emitting device includes a light-emitting element; and a light-reflective member. The light-emitting element includes a semiconductor structure body including an n-side layer, a p-side layer, and an active layer positioned between the n-side layer and the p-side layer, the n-side layer including an n-side exposed surface exposed from the active layer and the p-side layer in a plan view, the semiconductor structure body including a side surface connecting the n-side exposed surface and an upper surface of the p-side layer, an insulating film covering at least the side surface of the semiconductor structure body, the insulating film including a first opening exposing the n-side exposed surface, and a second opening positioned above the upper surface of the p-side layer, an n-side electrode including a first part positioned above the upper surface of the p-side layer with the insulating film interposed, a second part electrically connected with the n-side exposed surface in the first opening and electrically connected with the first part located at the insulating film covering the side surface of the semiconductor structure body, and a third opening in which the insulating film covering the side surface of the semiconductor structure body is exposed, and a p-side electrode electrically connected with the p-side layer in the second opening. The light-reflective member contacts the insulating film in the third opening.

According to certain embodiments of the disclosure, a light-emitting device in which the light extraction efficiency can be increased can be provided.

### BRIEF DESCRIPTION OF THE DRAWINGS

FIG. 1 is a schematic perspective view of a light-emitting device of an embodiment;

FIG. 2 is a schematic cross-sectional view of the light-emitting device of the embodiment;

FIG. 3 is a schematic plan view of a light-emitting element of the embodiment;

FIG. 4 is an enlarged schematic cross-sectional view of one portion of the light-emitting device of the embodiment;

FIG. 5 is a schematic plan view of a portion of the light-emitting element of the embodiment at which one n-side exposed surface is positioned;

FIG. 6 is a schematic plan view showing another example of a portion similar to FIG. 5;

FIG. 7 is a schematic plan view showing another example of a portion similar to FIG. 5; and

FIG. 8 is a schematic plan view showing another example of the light-emitting element of the embodiment.

### DETAILED DESCRIPTION

Light-emitting devices of embodiments will now be described with reference to the drawings. Unless specifically stated, the dimensions, materials, shapes, relative arrangements, and the like of the components according to the embodiments are not intended to limit the scope of the embodiments to those only, and are merely illustrative examples. The sizes, positional relationships, and the like shown in the drawings may be exaggerated for clarity of description. In the following description, the same names and reference numerals indicate the same or similar members, and a detailed description is omitted as appropriate. End views that show only cross sections may be used as cross-sectional views.

In the following description, terms that indicate specific directions or positions (e.g., “up,” “down,” and other terms including such terms) may be used. Such terms, however, are used merely for better understanding of relative directions or positions when referring to the drawings. As long as the relationships are the same, the relative directions or positions according to terms such as “up,” “down,” etc., used when referring to the drawings may not have the same arrangements in drawings, actual products, and the like outside the disclosure. In the specification, when assuming that there are, for example, two members, the positional relationship expressed as “up (or down)” includes the case where the two members are in contact, and the case where the two members are not in contact so that one of the members is positioned above (or below) the other member. Unless specifically stated, a member covering a covered object includes the case where the member contacts the covered object and directly covers the covered object, and the case where the member indirectly covers the covered object without contacting the covered object.

Directions may be indicated by an X-axis, a Y-axis, and a Z-axis in the drawings below. The X-axis, the Y-axis, and the Z-axis are orthogonal to each other. For example, in the specification, a direction along the X-axis is taken as a first direction X, a direction along the Y-axis is taken as a second direction Y, and a direction along the Z-axis is taken as a third direction Z.

A light-emitting device 1 of an embodiment includes a light-emitting element 100 and a light-reflective member 200. The light-emitting element 100 includes a semiconductor structure body 10, an insulating film 20, an n-side electrode 30, and a p-side electrode 40. The semiconductor structure body 10 includes an n-side layer 11, a p-side layer 13, and an active layer 12 positioned between the n-side layer 11 and the p-side layer 13. The n-side layer 11 includes an n-side exposed surface 11a exposed from the active layer 12 and the p-side layer 13 in a plan view. The semiconductor structure body 10 includes a side surface 10a connecting the n-side exposed surface 11a and an upper surface 13a of the p-side layer 13. The insulating film 20 includes a first opening 21 and a second opening 22. The first opening 21 covers at least the side surface of the semiconductor structure body 10. The n-side exposed surface 11a is exposed in the first opening 21. The second opening 22 is positioned above the upper surface 13a of the p-side layer 13. The n-side electrode 30 includes a first part 31, a second part 32, and a third opening 33. The first part 31 is positioned above the upper surface 13a of the p-side layer 13 with the insulating film 20 interposed therebetween. The second part 32 is electrically connected with the n-side exposed surface 11a in the first opening 21 and electrically connected with the first part 31 located at the insulating film 20 covering the side surface 10a of the semiconductor structure body 10. The insulating film 20 covering the side surface 10a of the semiconductor structure body 10 is exposed in the third opening 33. The p-side electrode 40 is electrically connected with the p-side layer 13 in the second opening 22. The light-reflective member 200 contacts the insulating film 20 in the third opening 33.

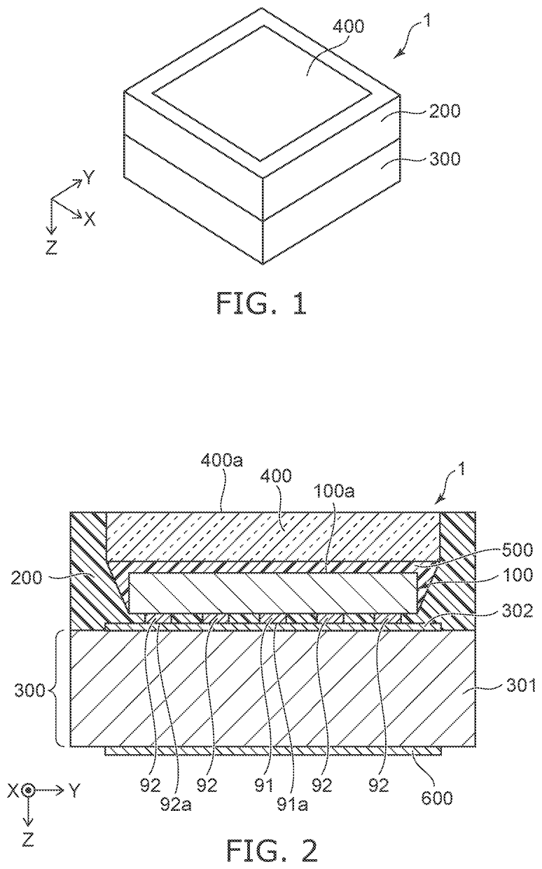

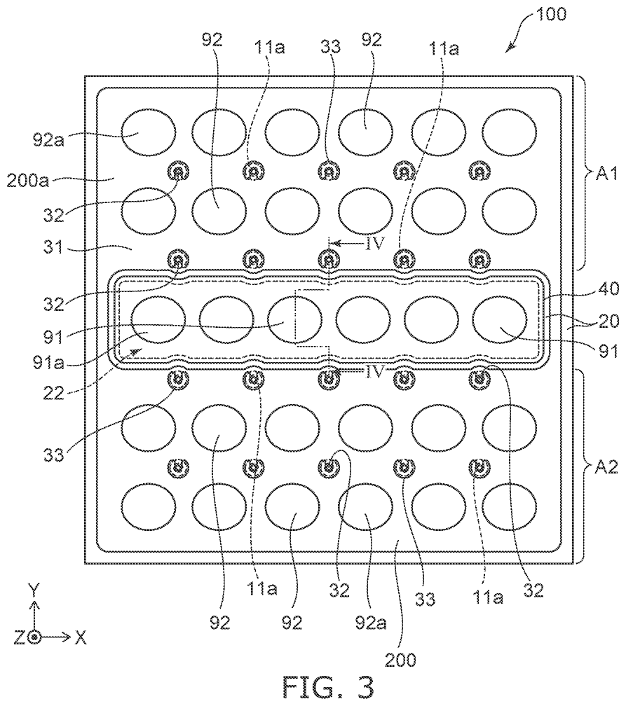

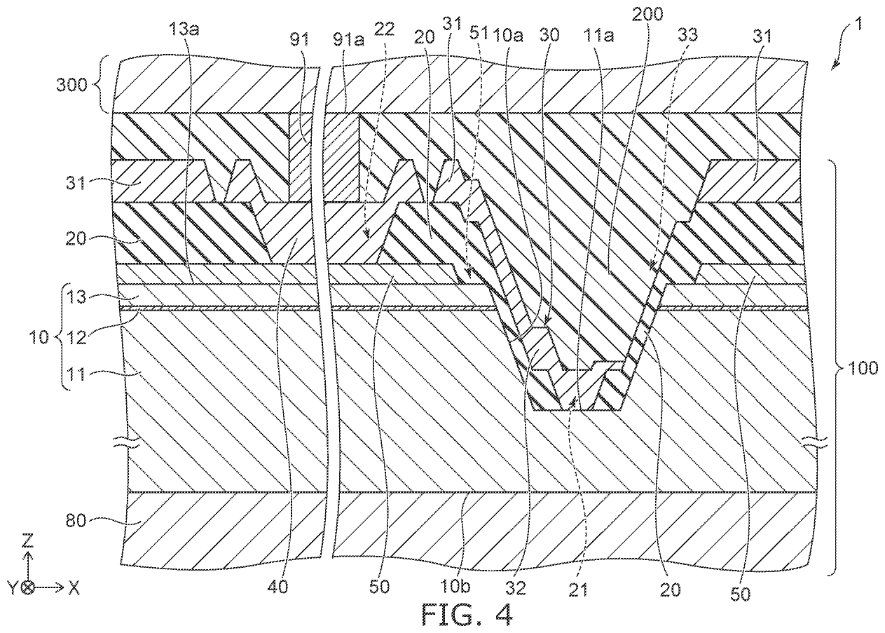

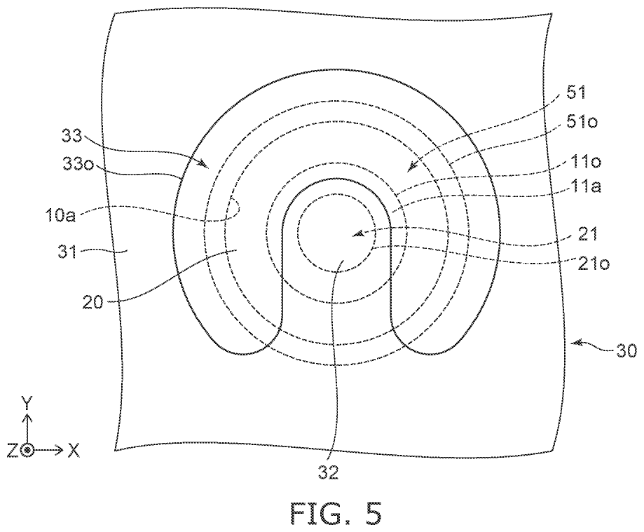

The light-emitting device 1 of the embodiment will now be described with reference to FIGS. 1 to 5. FIG. 1 is a schematic perspective view of the light-emitting device 1 of the embodiment. FIG. 2 is a schematic cross-sectional view of the light-emitting device 1 of the embodiment. FIG. 3 is a schematic plan view of the light-emitting element 100. FIG. 4 is an enlarged schematic cross-sectional view of one portion of the light-emitting device 1 including a detailed cross-sectional structure of the light-emitting element 100. The cross section of the light-emitting element 100 of FIG. 4 corresponds to the cross section along line IV-IV of FIG. 3. FIG. 5 is a schematic plan view of a portion of the light-emitting element 100 at which one n-side exposed surface 11a is positioned.

As shown in FIGS. 1 and 2, the light-emitting device 1 of the embodiment includes the light-emitting element 100 and the light-reflective member 200. The light-emitting device 1 of the embodiment can further include a wiring substrate 300, a light-transmitting member 400, a bonding member 500, and an external terminal 600. The configurations will now be elaborated.

### Light-Emitting Element

The light-emitting element 100 includes the semiconductor structure body 10, the insulating film 20, the n-side electrode 30, and the p-side electrode 40.

### Semiconductor Structure Body

The semiconductor structure body 10 is made of a nitride semiconductor. In the specification, “nitride semiconductor” includes, for example, all compositions of semiconductors of the chemical formula InₓAl_{y}Ga_{1-x-y}N (0≤x≤1, 0≤y≤1, and x+y≤1) for which the composition ratios x and y are changed within the ranges respectively. “Nitride semiconductor” further includes Group V elements other than N (nitrogen) in the chemical formula above, various elements added to control various properties such as the conductivity type, etc.

The semiconductor structure body 10 includes the n-side layer 11, the p-side layer 13, and the active layer 12. The active layer 12 is positioned between the n-side layer 11 and the p-side layer 13 in the third direction Z. The active layer 12 is a light-emitting layer that emits light, and has, for example, a MQW (Multiple Quantum well) structure including multiple barrier layers and multiple well layers. For example, the active layer 12 emits light having a light emission peak wavelength of not less than 210 nm and not more than 580 nm. The n-side layer 11 includes a semiconductor layer including an n-type impurity. The p-side layer 13 includes a semiconductor layer including a p-type impurity.

The semiconductor structure body 10 is located on a substrate 80. The n-side layer 11, the active layer 12, and the p-side layer 13 are formed in this order on the substrate 80. For example, a sapphire substrate can be used as the substrate 80. The light-emitting element 100 may not include the substrate 80.

As shown in FIG. 3, the n-side layer 11 includes the n-side exposed surface 11a exposed from the active layer 12 and the p-side layer 13 in a plan view. The n-side layer 11 includes, for example, multiple n-side exposed surfaces 11a. The semiconductor structure body 10 includes a light extraction surface 10b. As shown in FIG. 4, the light extraction surface 10b is the surface of the n-side layer 11 positioned at the side opposite to the n-side exposed surface 11a in the third direction Z. The light that is emitted by the active layer 12 is extracted outside the semiconductor structure body 10 mainly from the light extraction surface 10b. The p-side layer 13 includes an upper surface 13a positioned at the side opposite to the light extraction surface 10b in the third direction Z. The semiconductor structure body 10 includes the side surface 10a that connects the n-side exposed surface 11a and the upper surface 13a of the p-side layer 13. The side surface 10a of the semiconductor structure body 10 includes the side surface of the p-side layer 13 and the side surface of the active layer 12. The side surface 10a of the semiconductor structure body 10 also includes the side surface of the n-side layer 11 connected with the n-side exposed surface 11a.

### Insulating Film

As shown in FIG. 4, the insulating film 20 covers at least the side surface 10a of the semiconductor structure body 10. For example, the insulating film 20 covers the entire surface of the side surface 10a of the semiconductor structure body 10. In other words, the insulating film 20 covers the side surface of the p-side layer 13, the side surface of the active layer 12, and the side surface of the n-side layer 11 connected with the n-side exposed surface 11a. The insulating film 20 directly or indirectly covers the side surface 10a of the semiconductor structure body 10. For example, the insulating film 20 contacts the side surface 10a of the semiconductor structure body 10.

The insulating film 20 also may cover a portion of the n-side exposed surface 11a. For example, the insulating film 20 is located at the outer perimeter portion of the n-side exposed surface 11a in a top-view. The insulating film 20 includes a first opening 21 thin which the n-side exposed surface 11a is exposed.

The insulating film 20 also is located above the upper surface 13a of the p-side layer 13. The insulating film 20 includes the second opening 22 that is positioned above the upper surface 13a of the p-side layer 13.

For example, a silicon oxide film or a silicon nitride film can be used as the insulating film 20. The insulating film 20 is a single-layer film or a stacked film.

### N-Side Electrode

The n-side electrode 30 is electrically connected with the n-side layer 11. The n-side electrode 30 includes the first part 31 and the second part 32.

As shown in FIG. 4, the first part 31 is positioned above the upper surface 13a of the p-side layer 13 with the insulating film 20 interposed therebetween. By providing the first part 31 above the upper surface 13a of the p-side layer 13, an n-side external connection electrode 92 described below can be located at the first part 31. The surface area of the first part 31 is greater than the surface area of the n-side exposed surface 11a (when multiple n-side exposed surfaces 11a exist, the total surface area of the multiple n-side exposed surfaces 11a). Accordingly, the n-side external connection electrode 92 can be easily located at the first part 31.

As shown in FIG. 4, the second part 32 contacts the n-side exposed surface 11a in the first opening 21 of the insulating film 20, is electrically connected with the n-side exposed surface 11a, and is electrically connected with the first part 31 located at the insulating film 20 covering the side surface 10a of the semiconductor structure body 10. The n-side layer 11 is electrically connected to the first part 31 via the second part 32 connected with the n-side exposed surface 11a.

The insulating film 20 is positioned between the n-side electrode 30 and the upper surface 13a of the p-side layer 13, between the n-side electrode 30 and the side surface of the p-side layer 13, and between the n-side electrode 30 and the side surface of the active layer 12, and the n-side electrode 30 is not connected to the p-side layer 13 or the active layer 12.

As shown in FIG. 4, the n-side electrode 30 further includes the third opening 33. The insulating film 20 covering the side surface 10a of the semiconductor structure body 10 is exposed in the third opening 33. A portion of the insulating film 20 covering the side surface 10a of the semiconductor structure body 10 is covered with the second part 32 of the n-side electrode 30. At the insulating film 20 covering the side surface 10a of the semiconductor structure body 10, the third opening 33 is positioned at the part of the n-side electrode 30 not covered with the second part 32.

As shown in FIG. 3, the number of the n-side exposed surfaces 11a is equal to the number of the third openings 33. The n-side electrode 30 includes one third opening 33 for one n-side exposed surface 11a. The multiple n-side exposed surfaces 11a may include n-side exposed surfaces 11a for which the third opening 33 is not provided.

In FIG. 5, an outer edge 21o of the first opening 21 of the insulating film 20 and an outer edge 11 of the n-side exposed surface 11a are illustrated by circular broken lines. The outer edge 21o of the first opening 21 and the outer edge 11o of the n-side exposed surface 11a are not limited to circular in a plan view and may be polygonal. Circular is not limited to a perfect circle and includes shapes made of continuous closed curves.

In FIG. 5, an outer edge 33o of the third opening 33 of the n-side electrode 30 is illustrated by a solid line. For example, the outer edge 33o of the third opening 33 is made of a continuous closed curve in a plan view. As shown in FIG. 5, the outer edge 33o of the third opening 33 has, for example, a shape in which a portion of a circle has a convex curve toward the center of the circle. Alternatively, the outer edge 33o of the third opening 33 may be polygonal in a plan view.

In FIG. 5, the outer edge 33o of the third opening 33 is separated from, and does not overlap, the outer edge 21o of the first opening 21. A portion of the outer edge 33o of the third opening 33 overlaps a portion of the n-side exposed surface 11a. The insulating film 20 is exposed in a region inward of the outer edge 33o of the third opening 33. The first and second parts 31 and 32 of the n-side electrode 30 are continuous in the region outward of the outer edge 33o of the third opening 33.

### P-Side Electrode

The p-side electrode 40 is electrically connected with the p-side layer 13. As shown in FIG. 4, the p-side electrode 40 is electrically connected with the p-side layer 13 in the second opening 22 of the insulating film 20. As shown in FIG. 3, the p-side electrode 40 extends in the first direction X in a plan view. The second opening 22 also extends in the first direction X in a plan view.

The p-side electrode 40 is located on the insulating film 20 located above the upper surface 13a of the p-side layer 13. The p-side electrode 40 is separated from the n-side electrode 30 in a plan view. As shown in FIG. 4, for example, the light-reflective member 200 is located between the p-side electrode 40 and the n-side electrode 30 on the insulating film 20.

For example, silver, aluminum, nickel, rhodium, gold, copper, titanium, platinum, palladium, molybdenum, chrome, tungsten, or alloys including such metals as a major component can be used favorably as the materials of the n-side electrode 30 and the p-side electrode 40. The material of the n-side electrode 30 and the material of the p-side electrode 40 may be the same or different. The n-side electrode 30 and the p-side electrode 40 may be single layers of the metal materials recited above, or may have stacked structures including multiple metal layers.

### Light-Reflective Electrode

The light-emitting element 100 can further include a light-reflective electrode 50. As shown in FIG. 4, the light-reflective electrode 50 is located between the p-side electrode 40 and the upper surface 13a of the p-side layer 13 and is electrically connected with the p-side layer 13 and the p-side electrode 40. The light-reflective electrode 50 also has the function of diffusing the current supplied from the p-side electrode 40 in the planar direction of the p-side layer 13 (directions parallel to the XY plane).

The insulating film 20 that is located above the upper surface 13a of the p-side layer 13 covers the upper surface of the light-reflective electrode 50, the side surface of the light-reflective electrode 50, and the upper surface 13a of the p-side layer 13.

For example, the light-reflective electrode 50 is highly reflective to the light emitted by the active layer 12. Here, the light-reflective electrode 50 being highly reflective means having a reflectance of not less than 50%, and favorably not less than 60% for the light emission peak wavelength of the light emitted by the active layer 12. The light-reflective electrode 50 can include, for example, a metal layer including silver or aluminum.

The light-reflective electrode 50 includes a fourth opening 51 in which the n-side exposed surface 11a is exposed. In FIG. 5, an outer edge 51o of the fourth opening 51 is illustrated by a circular broken line. The outer edge 51o of the fourth opening 51 is not limited to circular and may be polygonal in a plan view.

The n-side exposed surface 11a and the first opening 21 of the insulating film 20 are positioned inward of the outer edge 510 of the fourth opening 51 of the light-reflective electrode 50 in a plan view.

### External Connection Electrodes

The light-emitting element 100 can further include a p-side external connection electrode 91 and the n-side external connection electrode 92. As shown in FIG. 4, the p-side external connection electrode 91 is located on the p-side electrode 40. The p-side external connection electrode 91 is electrically connected with the p-side layer 13 via the p-side electrode 40. As shown in FIG. 3, multiple p-side external connection electrodes 91 are arranged in a direction (the first direction X) in which the p-side electrode 40 extends.

The n-side external connection electrode 92 is located on the first part 31. The n-side external connection electrode 92 is electrically connected with the n-side layer 11 via the n-side electrode 30. As shown in FIG. 3, the light-emitting element 100 includes two regions separated in the second direction Y with the p-side electrode 40 extending in the first direction X interposed therebetween. One of the two regions of the light-emitting element 100 is taken as a first region A1, and the other of the two regions is taken as a second region A2. The multiple n-side external connection electrodes 92 are located in each of the first and second regions A1 and A2. The first part 31 of the n-side electrode 30 is located in the first and second regions A1 and A2. As shown in FIG. 3, by providing the multiple n-side external connection electrodes 92 at the first part 31, the heat dissipation can be improved because the contact area between the wiring substrate 300 and the n-side external connection electrodes 92 can be increased. The multiple n-side exposed surfaces 11a are located in each of the first and second regions A1 and A2.

For example, copper, gold, and nickel can be used as materials of the p-side external connection electrode 91 and the n-side external connection electrode 92. The p-side external connection electrode 91 and the n-side external connection electrode 92 may be single layers of these metal materials, or may have stacked structures include multiple metal layers.

### Light-Reflective Member

The light-reflective member 200 contacts the insulating film 20 in the third opening 33 of the n-side electrode 30. The light-reflective member 200 is located at the periphery of the light-emitting element 100. The light-reflective member 200 covers at least the side surface and lower surface of the light-emitting element 100. In FIG. 2, the light-reflective member 200 is located on the wiring substrate 300. The light-reflective member 200 also is located between the wiring substrate 300 and the light-emitting element 100. The light-reflective member 200 may have a single-layer structure or a stacked structure.

The light-reflective member 200 is highly reflective to the light emitted by the active layer 12. Here, the light-reflective member 200 being highly reflective means having a reflectance of not less than 60%, and favorably not less than 70% for the light emission peak wavelength of the light emitted by the active layer 12. The absorptance of the light-reflective member 200 for the light emitted by the active layer 12 is less than the absorptance of the n-side electrode 30 for the light emitted by the active layer 12.

The light-reflective member 200 includes a resin as a base material, and particles of a light-reflective substance included in the resin. A resin that includes at least one of a silicone resin, a modified silicone resin, an epoxy resin, a modified epoxy resin, an acrylic resin, or a fluorocarbon resin is an example of the resin of the light-reflective member 200. Titanium oxide, silicon oxide, zirconium oxide, potassium titanate, aluminum oxide, aluminum nitride, boron nitride, mullite, combinations of such substances, etc., are examples of the light-reflective substance of the light-reflective member 200. The average particle size of the light-reflective substance is, for example, in a range of 0.05 μm to 30 μm.

The light-reflective member 200 covers the insulating film 20, the n-side electrode 30, the p-side electrode 40, the side surface of the p-side external connection electrode 91, and the side surface of the n-side external connection electrode 92. A surface 91a of the p-side external connection electrode 91 at the side opposite to the surface connected with the p-side electrode 40 and a surface 92a of the n-side external connection electrode 92 at the side opposite to the surface connected with the n-side electrode 30 are exposed from the light-reflective member 200.

### Wiring Substrate

The light-emitting element 100 is located on the wiring substrate 300. The wiring substrate 300 includes an insulating base material 301, and a conductive member 302 located on the insulating base material 301. The conductive member 302 is electrically connected with the external terminal 600 described below via a conductive part located inside through-holes positioned inside the insulating base material 301. As shown in FIG. 2, the surface of the light-emitting element 100 that includes the surface 91a of the p-side external connection electrode 91 and the surface 92a of the n-side external connection electrode 92 is used as a mounting surface that faces the wiring substrate 300. For example, the surface 91a of the p-side external connection electrode 91 and the surface 92a of the n-side external connection electrode 92 are bonded with the conductive member 302 via a bonding member such as solder, etc. In the state in which the light-emitting element 100 is located on the wiring substrate 300, the light extraction surface 10b of the semiconductor structure body 10 is positioned at the side opposite to the surface of the light-emitting element 100 mounted to the wiring substrate 300. The p-side external connection electrode 91 and the n-side external connection electrode 92 may be located on the wiring substrate 300. In such a case, the n-side electrode 30 and the p-side electrode 40 of the light-emitting element 100 are bonded with the wiring substrate 300 that includes the p-side external connection electrode 91 and the n-side external connection electrode 92.

For example, aluminum nitride can be used as the material of the insulating base material 301. A material similar to that of the n-side external connection electrode 92 and the p-side external connection electrode 91 can be used as the material of the conductive member 302.

### External Terminal

The wiring substrate 300 may include the external terminal 600. As shown in FIG. 2, the external terminal 600 is located at the surface of the wiring substrate 300 at the side opposite to the surface at which the light-emitting element 100 is located. The p-side external connection electrode 91 and the n-side external connection electrode 92 of the light-emitting element 100 are electrically connected with the external terminal 600 via the conductive member 302 of the wiring substrate 300 and the conductive part positioned inside the through-holes. Electrical power is supplied to the light-emitting element 100 from an external circuit via the external terminal 600, the conductive member 302 of the wiring substrate 300, the p-side external connection electrode 91, and the n-side external connection electrode 92. A material similar to that of the n-side external connection electrode 92 and the p-side external connection electrode 91 can be used as the material of the external terminal 600.

The light that is emitted by the active layer 12 is extracted outside the light-emitting device 1 mainly via the light extraction surface 10b. The light that does not travel directly to the light extraction surface 10b from the active layer 12 can be oriented toward the light extraction surface 10b mainly by being reflected by the light-reflective member 200.

As shown in FIG. 4, the n-side electrode 30 includes the second part 32 and the third opening 33 at the side surface 10a of the semiconductor structure body 10 connected to the n-side exposed surface 11a. The second part 32 electrically connects the n-side exposed surface 11a and the first part 31. The insulating film 20 contacts the light-reflective member 200 in the third opening 33. Accordingly, the optical absorption by the n-side electrode 30 in the third opening 33 can be reduced while ensuring the electrical connection between the n-side exposed surface 11a and the first part 31 by the second part 32, and the reflectance by the light-reflective member 200, which has less optical absorption than the n-side electrode 30, can be increased. As a result, the light extraction efficiency from the light extraction surface 10b can be increased. When the light-reflective electrode 50 is located on the upper surface 13a of the p-side layer 13, the light extraction efficiency from the light extraction surface 10b can be increased by the reflection by the light-reflective electrode 50.

As shown in FIG. 5, it is favorable for a portion of the outer edge 33o of the third opening 33 (the part next to the second part 32) to be positioned inward of the outer edge 11 of the n-side exposed surface 11a in a plan view. The contact area between the n-side layer 11 and the n-side electrode 30 at the n-side exposed surface 11a can be ensured thereby.

As shown in FIG. 5, it is favorable for a portion of the outer edge 33o of the third opening 33 (the part not next to the second part 32) to be positioned further outward than the outer edge 51o of the fourth opening 51 of the light-reflective electrode 50 in a plan view. Accordingly, the optical absorption by the n-side electrode 30 at the side surface 10a of the semiconductor structure body 10 can be less than when a portion of the outer edge 33o of the third opening 33 is positioned further inward than the outer edge 51o of the fourth opening 51 of the light-reflective electrode 50. The part at which the outer edge 33o of the third opening 33 and the outer edge 51o of the fourth opening 51 of the light-reflective electrode 50 overlap in a plan view can be reduced, and it is easier to discriminate between the third opening 33 and the fourth opening 51 in an inspection process.

As shown in FIG. 3, the multiple third openings 33 are separated from each other in a plan view. The second parts 32 are connected respectively to the n-side exposed surfaces 11a. The second parts 32 that are connected respectively to the n-side exposed surfaces 11a are connected with the first part 31 located in the first and second regions A1 and A2.

The second part 32 that is connected with at least one n-side exposed surface 11a among the multiple n-side exposed surfaces 11a is positioned between the third opening 33 and the p-side electrode 40 in the second direction Y in a plan view. The second parts 32 that are located in the first region A1 extend in the negative direction of the Y-axis from the centers of the n-side exposed surfaces 11a toward the p-side electrode 40 in a plan view. The second parts 32 that are located in the second region A2 extend in the positive direction of the Y-axis from the centers of the n-side exposed surfaces 11a toward the p-side electrode 40 in a plan view. The second part 32 is positioned in a region including an imaginary straight line having the shortest distance between the p-side electrode 40 and the center of the n-side exposed surface 11a in a plan view. The current loss in the path between the p-side electrode 40 and the n-side exposed surface 11a can be reduced thereby, and the forward voltage of the light-emitting device 1 can be reduced.

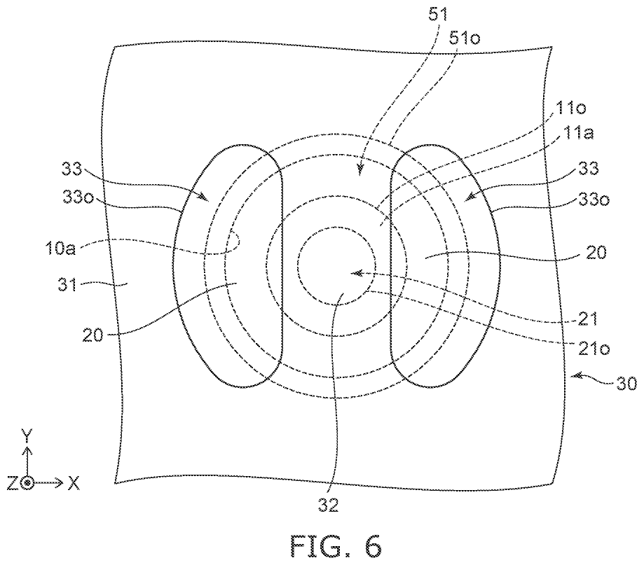

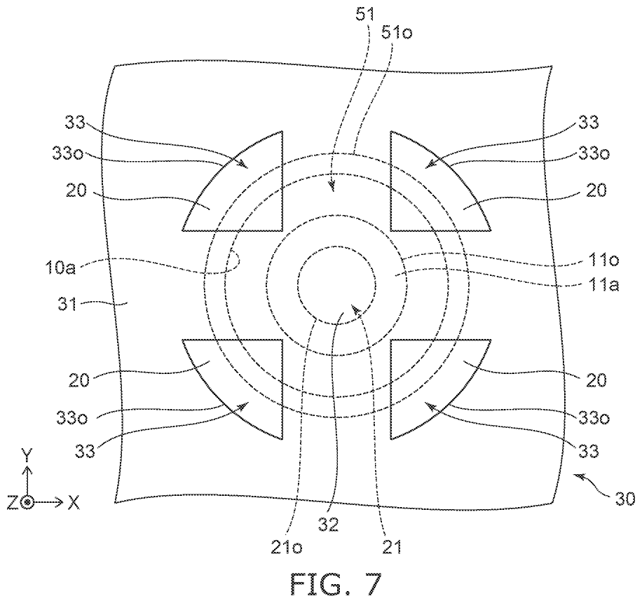

FIGS. 6 and 7 are schematic plan views showing other examples of portions similar to FIG. 5. In the examples shown in FIGS. 6 and 7, the n-side electrode 30 includes multiple third openings 33 positioned above the side surface 10a of the semiconductor structure body 10 next to one n-side exposed surface 11a in a plan view.

In the example shown in FIG. 6, two third openings 33 are positioned away from each other with the center of one n-side exposed surface 11a interposed therebetween in the first direction X in a plan view. The second part 32 is positioned between the two third openings 33 next to each other in the first direction X in a plan view. The second part 32 is connected with the first part 31 at two locations at two end sides in the second direction Y. Accordingly, current concentration in the second part 32 can be less than when the first part 31 and the second part 32 are connected at one location for one n-side exposed surface 11a. In FIG. 6, the outer edge 33o of the third opening 33 has a substantially elliptical shape extending in the second direction Y.

As shown in FIG. 7, four third openings 33 that are separated from each other in the first and second directions X and Y are positioned to be point-symmetric with respect to the center of one n-side exposed surface 11a in a plan view. The second part 32 is positioned between two of the four third openings 33 next to each other in the first direction X and between two of the four third openings 33 next to each other in the second direction Y in a plan view. In such a case, the first part 31 and the second part 32 are connected at four locations for one n-side exposed surface 11a. Current concentration in the second part 32 can be reduced thereby. The third opening 33 has a fan-like shape in a plan view. The shapes of the outer edges 33o of the four third openings 33 may be the same or different. The third openings 33 are positioned outward of the outer edge 110 of the n-side exposed surface 11a. The contact area between the n-side layer 11 and the n-side electrode 30 can be ensured thereby.

The n-side electrode 30 may include three, five, or more third openings 33 positioned above the side surface 10a of the semiconductor structure body 10 next to one n-side exposed surface 11a in a plan view.

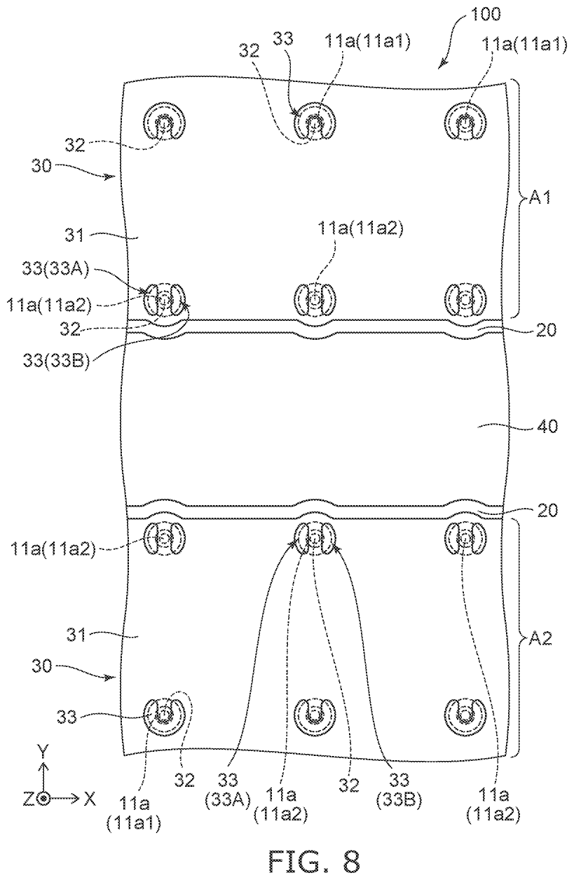

FIG. 8 is a schematic plan view showing another example of the light-emitting element 100 of the embodiment.

The n-side layer 11 includes the multiple n-side exposed surfaces 11a that include a first n-side exposed surface 11a1 and a second n-side exposed surface 11a2 next to each other in the second direction Y in each of the first and second regions A1 and A2 positioned with the p-side electrode 40 interposed therebetween in the second direction Y. The second n-side exposed surface 11a2 is positioned closer to the p-side electrode 40 than the first n-side exposed surface Hal in the second direction Y

The n-side electrode 30 includes the multiple third openings 33 that include a third A opening 33A and a third B opening 33B separated from each other in the first direction X and positioned above the side surface 10a of the semiconductor structure body 10 next to the second n-side exposed surface 11a2. The third A opening 33A and the third B opening 33B are positioned with the center of the second n-side exposed surface 11a2 interposed therebetween in the first direction X. In other words, the two third openings 33 shown in FIG. 6 above are positioned above the side surface 10a of the semiconductor structure body 10 next to one second n-side exposed surface 11a2. The second part 32 of the n-side electrode 30 connected to the second n-side exposed surface 11a2 is positioned between the third A opening 33A and the third B opening 33B in a plan view. The second part 32 is connected with the first part 31 at the end portions at two locations in the second direction Y The second part 32 that is connected to the first n-side exposed surface 11al is positioned between the second n-side exposed surface 11a2 and the third opening 33 positioned above the side surface 10a of the semiconductor structure body 10 next to the first n-side exposed surface 11al in a plan view.

In FIG. 8, the second part 32 that is connected to the second n-side exposed surface 11a2 at the position proximate to the p-side electrode 40 is connected with the first part 31 at the end portions at two locations in the second direction Y The second part 32 that is connected to the first n-side exposed surface 11al at the position more distant to the p-side electrode 40 than the second n-side exposed surface 11a2 in the second direction Y is connected with the first part 31 at the side proximate to the p-side electrode 40 in the second direction Y. The current loss in the path between the p-side electrode 40 and the first n-side exposed surface 11al can be reduced thereby, and the forward voltage of the light-emitting device 1 can be reduced.

In FIG. 8, the third A opening 33A and the third B opening 33B have shapes similar to those of the two third openings 33 shown in FIG. 6. In FIG. 8, one third opening 33 positioned above the side surface 10a of the semiconductor structure body 10 next to one first n-side exposed surface 11al has a shape similar to that of the third opening 33 shown in FIG. 5.

### Light-Transmitting Member

In the light-emitting device 1, the light-transmitting member 400 may be located above a light-emitting surface 100a of the light-emitting element 100. The light-emitting surface 100a of the light-emitting element 100 is a surface at the light extraction surface 10b side of the semiconductor structure body 10, and when the light-emitting element 100 includes the substrate 80, is the surface of the substrate 80 positioned at the side opposite to the surface at which the semiconductor structure body 10 is located. As shown in FIG. 1, an upper surface 400a of the light-transmitting member 400 is exposed from the light-reflective member 200. In the light-emitting device 1, the light that is emitted by the active layer 12 is extracted outside mainly from the upper surface 400a of the light-transmitting member 400. As shown in FIG. 2, the side surface of the light-transmitting member 400 is covered with the light-reflective member 200.

For example, a light-transmitting resin, glass, a ceramic, etc., can be used as the light-transmitting member 400. A resin that includes at least one of a silicone resin, a modified silicone resin, an epoxy resin, a modified epoxy resin, an acrylic resin, or a fluorocarbon resin can be used as the material of the light-transmitting resin.

The light-transmitting member 400 also can include a phosphor capable of wavelength conversion of at least a portion of the incident light. An yttrium-aluminum-garnet-based phosphor (e.g., (Y, Gd)₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂:Eu), an SAE-based phosphor (e.g., Sr₄Al₁₄O₂₅:Eu), a chlorosilicate-based phosphor (e.g., Ca₈MgSi₄O₁₆Cl₂:Eu), a silicate-based phosphor (e.g., (Ba, Sr, Ca, Mg)₂SiO₄:Eu), an oxynitride-based phosphor such as a β-sialon-based phosphor (e.g., (Si, Al)₃(O, N)₄:Eu), an α-sialon-based phosphor (e.g., Ca(Si, Al)₁₂(O, N)₁₆:Eu), or the like, a nitride-based phosphor such as an LSN-based phosphor (e.g., (La, Y)₃Si₆N₁₁:Ce), a BSESN-based phosphor (e.g., (Ba, Sr)₂Si₅N₈:Eu), an SLA-based phosphor (e.g., SrLiAl₃N₄:Eu), a CASN-based phosphor (e.g., CaAlSiN₃:Eu), a SCASN-based phosphor (e.g., (Sr, Ca)AlSiN₃:Eu), or the like, a fluoride-based phosphor such as a KSF-based phosphor (e.g., K₂SiF₆:Mn), a KSAF-based phosphor (e.g., K₂(Si₁₋ₓAlₓ)F₆₋ₓ:Mn, where x satisfies 0<x<1), a MGF-based phosphor (e.g., 3.5MgO·0.5MgF₂·GeO₂:Mn), or the like, a quantum dot having a perovskite structure (e.g., (Cs, FA, MA)(Pb, Sn)(F, Cl, Br, I)₃, where FA and MA are respectively formamidinium and methylammonium), a Group II-VI quantum dot (e.g., CdSe), a Group III-V quantum dot (e.g., InP), a quantum dot having a chalcopyrite structure (e.g., (Ag, Cu)(In, Ga)(S, Se)₂), etc., can be used as the phosphor. The light-transmitting member 400 may include a single type of phosphor or multiple types of phosphors.

The light-transmitting member 400 that includes a phosphor may be a phosphor-including layer such as a phosphor-including resin layer or the like located on the surface of a light-transmitting layer that is a formed body of a light-transmitting resin, glass, a ceramic, etc. A sintered body of a phosphor or a phosphor powder included in a light-transmitting resin, glass, a ceramic, etc., also may be used. The light-transmitting member 400 that includes a phosphor may be, for example, formed by sintering a phosphor and a light-transmitting material such as aluminum oxide, etc. Substantially only a phosphor formed by sintering a phosphor powder without using a light-transmitting material may be used. It is favorable for the light-transmitting member 400 including the phosphor to be a sintered body of yttrium-aluminum·garnet.

### Bonding Member

The light-transmitting member 400 can be bonded to the light-emitting element 100 by the bonding member 500. A resin similar to the resin included in the light-transmitting member 400 can be used as the bonding member 500. The light-transmitting member 400 may be directly bonded with the light-emitting element 100. As shown in FIG. 2, the bonding member 500 is covered with the light-reflective member 200.

When the light-emitting device 1 includes the bonding member 500, the light-reflective member 200 covers the bonding member 500. The side surface of the light-transmitting member 400 may be covered with a cover member other than the light-reflective member 200 that covers the side surface of the light-emitting element 100.

Hereinabove, embodiments of the disclosure are described with reference to specific examples. However, the invention is not limited to these specific examples. All configurations practicable by an appropriate design modification by one skilled in the art based on the embodiments of the disclosure described above also are within the scope of the invention to the extent that the purport of the invention is included. Various other variations and modifications can be conceived by those skilled in the art within the spirit of the invention, and it is understood that such variations and modifications are also encompassed within the scope of the invention.

What is claimed is:

1. A light-emitting device comprising:
a light-emitting element comprising:
a semiconductor structure body comprising an n-side layer, a p-side layer, and an active layer positioned between the n-side layer and the p-side layer, the n-side layer including an n-side exposed surface exposed from the active layer and the p-side layer in a plan view, the semiconductor structure body including a side surface connecting the n-side exposed surface and an upper surface of the p-side layer,
an insulating film covering at least the side surface of the semiconductor structure body, the insulating film including:
a first opening in which the n-side exposed surface is exposed, and
a second opening positioned above the upper surface of the p-side layer,
an n-side electrode comprising:
a first part positioned above the upper surface of the p-side layer with the insulating film interposed therebetween,
a second part electrically connected with the n-side exposed surface in the first opening and electrically connected with the first part located at the insulating film covering the side surface of the semiconductor structure body, and
a third opening in which the insulating film covering the side surface of the semiconductor structure body is exposed, and
a p-side electrode electrically connected with the p-side layer in the second opening; and
a light-reflective member contacting the insulating film in the third opening.

2. The device according to claim 1, further comprising:
a light-reflective electrode located between the p-side electrode and the upper surface of the p-side layer and electrically connected with the p-side layer and the p-side electrode.

3. The device according to claim 2, wherein:
the light-reflective electrode includes a fourth opening in which the n-side exposed surface is exposed, and
a portion of an outer edge of the third opening is positioned further outward than an outer edge of the fourth opening in a plan view.

4. The device according to claim 1, wherein:
the second part is positioned between the third opening and the p-side electrode in a plan view.

5. The device according to claim 2, wherein:
the second part is positioned between the third opening and the p-side electrode in a plan view.

6. The device according to claim 3, wherein:
the second part is positioned between the third opening and the p-side electrode in a plan view.

7. The device according to claim 1, wherein:
the n-side layer comprises a plurality of the n-side exposed surfaces, and
the n-side electrode comprises a plurality of the third openings positioned above the side surface of the semiconductor structure body next to one of the n-side exposed surfaces in a plan view.

8. The device according to claim 2, wherein
the n-side layer comprises a plurality of the n-side exposed surfaces, and
the n-side electrode comprises a plurality of the third openings positioned above the side surface of the semiconductor structure body next to one of the n-side exposed surfaces in a plan view.

9. The device according to claim 3, wherein:
the n-side layer comprises a plurality of the n-side exposed surfaces, and
the n-side electrode comprises a plurality of the third openings positioned above the side surface of the semiconductor structure body next to one of the n-side exposed surfaces in a plan view.

10. The device according to claim 7, wherein:
the p-side electrode extends in a first direction in a plan view, and
the second part is positioned between two third openings among the plurality of third openings next to each other in the first direction in a plan view.

11. The device according to claim 8, wherein:
the p-side electrode extends in a first direction in a plan view, and
the second part is positioned between two third openings among the plurality of third openings next to each other in the first direction in a plan view.

12. The device according to claim 9, wherein:
the p-side electrode extends in a first direction in a plan view, and
the second part is positioned between two third openings among the plurality of third openings next to each other in the first direction in a plan view.

13. The device according to claim 10, wherein:
the second part is positioned between two third openings among the plurality of third openings next to each other in a second direction orthogonal to the first direction in a plan view.

14. The device according to claim 11, wherein:
the second part is positioned between two third openings among the plurality of third openings next to each other in a second direction orthogonal to the first direction in a plan view.

15. The device according to claim 12, wherein:
the second part is positioned between two third openings among the plurality of third openings next to each other in a second direction orthogonal to the first direction in a plan view.

16. The device according to claim 1, wherein:
the p-side electrode extends in a first direction in a plan view,
the n-side layer includes a plurality of the n-side exposed surfaces,
the plurality of n-side exposed surfaces includes a first n-side exposed surface and a second n-side exposed surface next to each other in a second direction orthogonal to the first direction,
the second n-side exposed surface is positioned closer the p-side electrode than is the first n-side exposed surface in the second direction,
the n-side electrode includes a plurality of the third openings including a third A opening and a third B opening,
the third A opening and the third B opening are separated from each other in the first direction and positioned above the side surface of the semiconductor structure body next to the second n-side exposed surface,
the second part connected to the second n-side exposed surface is positioned between the third A opening and the third B opening in a plan view, and
the second part connected to the first n-side exposed surface is positioned between the second n-side exposed surface and the third opening positioned above the side surface of the semiconductor structure body next to the first n-side exposed surface in a plan view.

17. The device according to claim 2, wherein:
the p-side electrode extends in a first direction in a plan view,
the n-side layer includes a plurality of the n-side exposed surfaces,
the plurality of n-side exposed surfaces includes a first n-side exposed surface and a second n-side exposed surface next to each other in a second direction orthogonal to the first direction,
the second n-side exposed surface is positioned closer to the p-side electrode than is the first n-side exposed surface in the second direction,
the n-side electrode includes a plurality of the third openings including a third A opening and a third B opening,
the third A opening and the third B opening are separated from each other in the first direction and positioned above the side surface of the semiconductor structure body next to the second n-side exposed surface,
the second part connected to the second n-side exposed surface is positioned between the third A opening and the third B opening in a plan view, and
the second part connected to the first n-side exposed surface is positioned between the second n-side exposed surface and the third opening positioned above the side surface of the semiconductor structure body next to the first n-side exposed surface in a plan view.

18. The device according to claim 3, wherein:
the p-side electrode extends in a first direction in a plan view,
the n-side layer includes a plurality of the n-side exposed surfaces,
the plurality of n-side exposed surfaces includes a first n-side exposed surface and a second n-side exposed surface next to each other in a second direction orthogonal to the first direction,
the second n-side exposed surface is positioned closer to the p-side electrode than is the first n-side exposed surface in the second direction,
the n-side electrode includes a plurality of the third openings including a third A opening and a third B opening,
the third A opening and the third B opening are separated from each other in the first direction and positioned above the side surface of the semiconductor structure body next to the second n-side exposed surface,
the second part connected to the second n-side exposed surface is positioned between the third A opening and the third B opening in a plan view, and
the second part connected to the first n-side exposed surface is positioned between the second n-side exposed surface and the third opening positioned above the side surface of the semiconductor structure body next to the first n-side exposed surface in a plan view.
